(19) United States
(12) Patent Application Publication
(10) Pub. No.: US 2019/0187493 A1
(43) Pub. Date: Jun. 20, 2019

(54) BREAKDOWN VOLTAGE ENHANCEMENT TECHNIQUES FOR A HIGH SPEED AMPLIFIER

(71) Applicant: Fmax Technologies, Inc., Eden Prairie, MN (US)

(72) Inventor: Iain Ross Mactaggart, Eden Prairie, MN (US)

(21) Appl. No.: 16/227,867

(22) Filed: Dec. 20, 2018

Related U.S. Application Data
(60) Provisional application No. 62/608,336, filed on Dec. 20, 2017.

(51) Int. Cl. G02F 1/01; H03F 1/08; H03F 3/45; H03F 3/217

(52) U.S. Cl. CPC G02F 1/0121; H03F 1/083; H03F 3/45085; H03F 2203/45316; H03F 2203/45151; H03F 2203/45374; H03F 3/217

(57) ABSTRACT

Techniques for providing a modulation driver signal are disclosed. In an example, a modulation driver can include a first transistor configured to receive a first input signal having a first voltage swing, a second transistor coupled in series with the first transistor, and a third transistor configured to limit a third voltage swing across the second transistor. The second transistor can be configured to provide a representation of the first input signal as a first output signal of the modulator driver. The first output signal can have a second voltage swing greater than the first voltage swing.

### CLAIM OF PRIORITY

This patent application claims the benefit of priority of Mactaggart, U.S. Provisional Patent Application Ser. No. 62/608,336, entitled “BREAKDOWN VOLTAGE ENHANCEMENT TECHNIQUES FOR A HIGH-SPEED AMPLIFIER,” filed on Dec. 20, 2017 (Attorney Docket No. 3377.006PRV), which is hereby incorporated by reference herein in its entirety.

### BACKGROUND

Processors and associated applications have developed to a level that enable enormous amounts of information to be generated and utilized. The capability of processors and associated applications to utilize vast amounts of information spurs the development of communication systems that enable the dissemination of such vast amounts of information. Communication systems are under constant pressure to increase the bandwidth available for distribution of information.

A communication system can have sufficient bandwidth allocated for distribution of vast amounts of information, but the rate that the information can be distribute across the communication system may be limited by the limitations of the communications hardware. The operating bandwidth of integrated circuits used in conjunction with high speed communication systems has continued to increase to help satisfy the desire to increase communication rates.

Transistors can play an integral part of providing high-band width communications, the pursuit of high speed technology has taught that reducing the size of the transistors generally reduces barriers to achieving higher bandwidths. Reducing the physical size of individual transistors reduces the parasitic effects, such as parasitic capacitance, that can reduce the bandwidth of the transistor. The operating voltage and the breakdown voltage of the transistors can be reduced due, in part, to the physical reduction in size. Although a reduction in the operating voltage can provide some benefits in the form of reduced power consumption, the combination of reduced operating voltage and reduced breakdown voltage can severely limit the applicability of integrated circuits implementing such high-speed transistors.

### BRIEF DESCRIPTION OF THE DRAWINGS

FIG. 1 illustrates generally an example high speed communication system for modulating a high speed signal.

FIG. 2 illustrates generally an example modulator driver.

FIG. 3 illustrates generally an example high-speed amplifier output stage.

FIG. 4 illustrates generally a flowchart of an example method of operation a modulator driver according to the preset subject matter.

### DETAILED DESCRIPTION

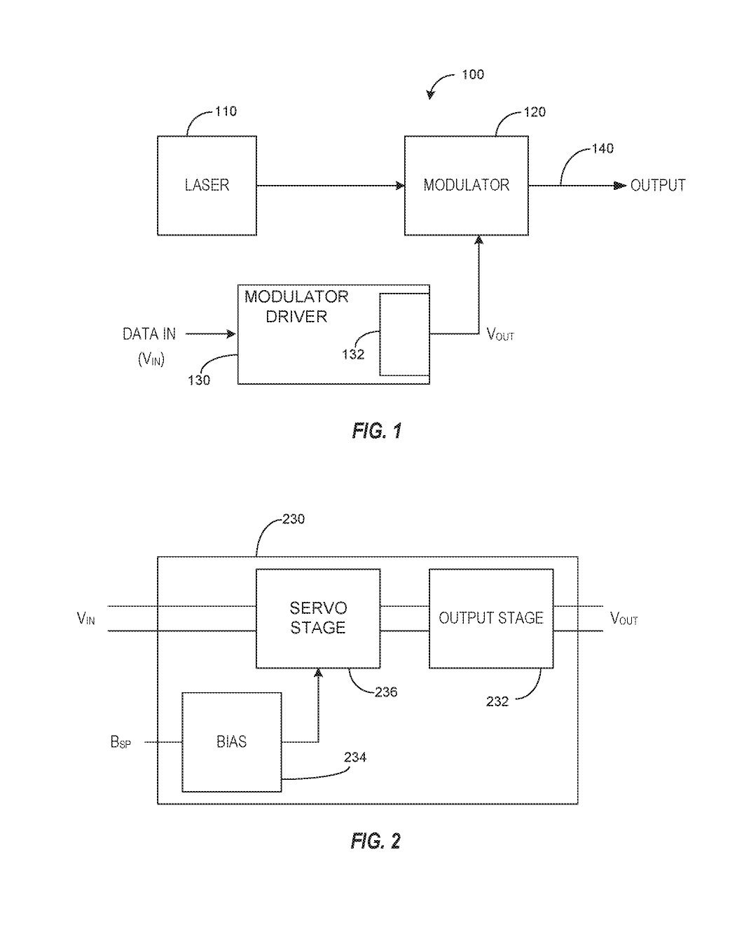

The present inventor has recognized techniques to overcome low breakdown voltage limitation of high-speed amplifiers that include high-speed, high-voltage swing transistor circuits. FIG. 1 illustrates generally an example high speed communication system for modulating a high speed signal, such as an optical modulator although the present techniques are not limited to such applications. As used herein, the term “high speed,” when used in connection with the description of a communication link or rate, can be interpreted to mean those systems, links, or communication rates for which the integrated circuits typically use transistors of reduced physical size and reduced operating voltages. For example, a high-speed communication system can have a data rate that is about 40 GHz or higher.

There are several breakdown voltages that are often reported for bipolar junction transistors (BJT). The collector-emitter breakdown voltage, B_{Vce}, is typically the main limiting factor in the design of a high-voltage driver. This breakdown voltage is a function of the total base resistance, R_{B}, to an AC ground. The most commonly reported value is the collector-emitter breakdown voltage when the base is open, i.e. when R_{B}=∞. It is noteworthy that B_{Vce} is the lower bound of the collector-emitter breakdown voltage of the transistor. The value of breakdown voltage increases when the base is driven with a lower source impedance. For example, B_{Vce}=1.8V for R_{B}=∞ compared to B_{Vce}>3.0V for R_{B}<1000. The dependence on source impedance can be exploited in the designs of driver output stages utilizing breakdown voltage enhancement.

High-speed drivers typically use some form of a current steering or current switch at the output stage. When a single active device withstands the entire output voltage swing, B_{Vce} sets the limit on the maximum output voltage. By distributing the output voltage swing across multiple transistors, the output voltage swing can exceed the breakdown voltage of any individual transistor in the output stage.

The communication system 100 can include carrier signal generator such as a laser 110 to provide a carrier signal. The laser 110 can be coupled to a modulator 120 that can be configured to amplitude modulate the laser 110 optical output, a laser signal or optical signal, based on a received modulation signal. A modulation driver 130 can be configured to receive a modulation signal and amplify it using a driver configuration that includes a breakdown enhancement output stage 132. The modulation signal can represent the information to be transmitted to a remote destination. The output of the modulation driver 130 can be coupled to the modulation input of the modulator 120 to modulate the optical signal.

The modulated signal output from the modulator 120 can be coupled to a channel, such as an optical fiber 140. The optical fiber 140 can be configured to couple the modulated optical signal to a remote destination. Although the optical fiber 140 is shown as a direct link, a communication channel may include one or more intervening elements, such as switches, couplers, and amplifiers.

While most of the building blocks in a fiber optic communication system 100 can be implemented in silicon for high speed communication links operating at 10 Gb/s and above, the optical modulator electrical driver 130 has been primarily done in compound semiconductors. This is mainly due to breakdown limitations of silicon transistors and large voltage swings used to operate the high-speed optical modulators 120. However, the process technology disparity between a compound semiconductor driver and the remainder of the transceiver can result in additional cost and performance penalties. The driver 130 can include an output stage 132 including a breakdown voltage enhancement circuit that overcomes the breakdown limitations of high-frequency transistors. The output stage 130 employing the breakdown voltage enhancement circuit 132 can enable high-speed broadband drivers 120 manufactured in silicon to have a large voltage swing, and in particular, a voltage swing that exceeds the breakdown voltage of the individual transistor in the output stage 132 that experience a portion of the voltage swing.

Existing electro-absorption and Mach-Zehnder (MZ) optical modulators 120 typically require voltage swings in the range of 3 volts or more to achieve a high extinction ratio. That is, these voltage swings are typically required to effectively switch the light on and off. Such a large voltage swing poses a challenge for silicon-based transistors (SiGe HBT or Si CMOS) whose breakdown voltages can decrease when the transistors are scaled for higher speed. While there have been reports of driver circuits in SiGe for optical applications, these circuits typically drop the entire voltage swing across single transistors and thus cannot exceed the collector-emitter breakdown voltages and are hence limited to a voltage swing approximately equal to the breakdown voltage of a single transistor manufactured according to SiGe processes, which can be typically be less than 3 volts.

FIG. 2 illustrates generally an example modulator driver 230. In certain examples, the modulator driver can include a bias generator 234, a servo stage 236, and an output stage 232 that includes a breakdown voltage enhancement circuit. The bias generator 234 can provide a bias voltage to a servo stage 236. The servo stage 236 can receive the digital data and can provide an analog command signal for the output stage 232 while also managing the common voltage point of the output stage 232. The output stage 232 can provide an analog commend signal to the modulator.

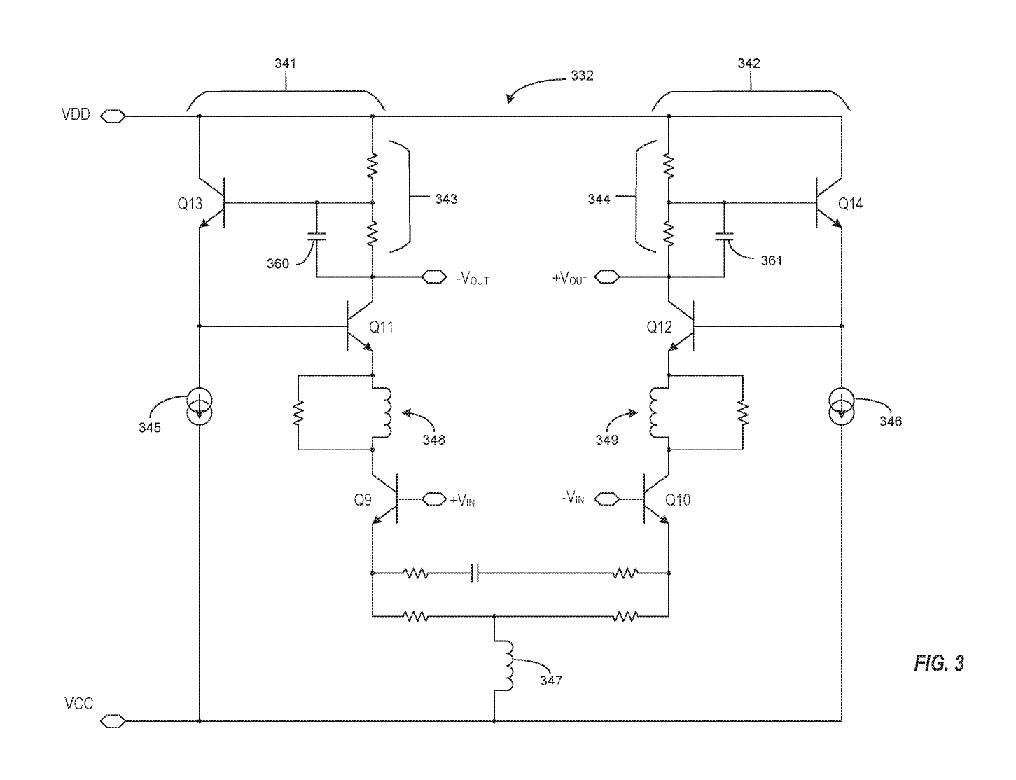

FIG. 3 illustrates generally an example high-speed amplifier output stage 332. In certain applications, the amplifier 332 can provide a 3-volt peak-to-peak voltage swing or greater with 45 GHz or more bandwidth. Such applications can include, but are not limited to, phase modulation, optical phase modulation, etc. The high-speed amplifier 332 can be a differential high-speed amplifier and can include two circuit branches 341, 342, a resistor network to set a DC bias and a resistor-capacitor-resistor network to provide frequency enhancement so as to extend the bandwidth as the circuit approaches a natural roll-off at ever higher frequencies. Each branch 341, 342 can be configured to receive an input signal (V_{IN}) and provide an output signal (V_{OUT}). In certain examples, the input voltage signal (V_{IN}) can have a voltage swing of a couple hundred millivolts and the output voltage (V_{OUT}) can be around 3 volts or higher. Each branch 341, 342 can include an input transistor (Q9, Q10), a buffer transistor (Q11, Q12) and a buffer driver transistor Q13, Q14. Each transistor can be a high transit frequency transistor. Such transistors have reduced size which can translate into reduced parasitic characteristics that typically limit bandwidth. Such transistors also have reduced breakdown voltages. However, each branch 341, 342 of the high-speed amplifier 332 stacks the input transistor (Q9, Q10) with a similar type buffer transistor (Q11, Q12). The stacking allows the high-speed amplifier 332 to provide output voltage swings that are higher than the individual breakdown voltage of each of the input transistor (Q9, Q10), the buffer transistor (Q11, Q12) and the buffer driver transistor (Q11, Q12).

Some conventional differential input stages would provide an output voltage at the collector of the input transistor. However, such an approach for a high-speed transistor would limit the output voltage swing to less than the break down voltage of the input transistor. To overcome this limitation, traditional techniques can stack the input transistor with a high breakdown voltage transistor having a control node coupled to a fixed reference. Such a technique can provide additional output voltage swing greater than the breakdown voltage of the input transistor, however, high breakdown voltage devices are typically larger and include parasitic capacitance electrical characteristics, for example parasitic capacitance, that renders such an arrangement unsuitable for high-speed applications of, for example, 45 GHz.

The present solution, as briefly discussed above, stacks two high-speed, low breakdown voltage transistors to provide a high-speed, high voltage swing solution. In addition, various examples, can derive a drive signal for one of the stacked transistors using a representation of the output voltage (V_{OUT}) which can limit the voltage swing across the other stacked transistor. In the illustrated solution, the drive circuitry of the second, or buffer transistor (Q11, Q12), is executed to also limit the voltage swing across the buffer transistor (Q11, Q12). In the illustrated example of FIG. 3, each of the input transistor (Q9, Q10) and the buffer transistor (Q11, Q12) can accommodate a portion of the full voltage swing of the output voltage (V_{OUT}). To limit the voltage swing across the buffer transistor (Q11, Q12), a buffer driver transistor (Q13, Q14) and voltage divider 343, 344 can be employed.

The buffer driver transistor (Q13, Q14) can be biased with a current source 345, 346 and can be arranged as an emitter follower with the emitter coupled to the control node of the buffer transistor (Q11, Q12). The voltage divider 343, 344 coupled in series with the collector of the buffer transistor (Q11, Q12) can scale the voltage swing of the buffer transistor (Q11, Q12) via the buffer driver transistor (Q13, Q14). In the illustrated example, each of the two resistors of the voltage divider 343, 344 can be equal to scale the voltage swing of the buffer transistor (Q11, Q12) to be half of the output voltage swing of the high-speed amplifier 332. The capacitive parasitic of the buffer transistor (Q11, Q12) and the buffer driver transistor (Q13, Q14), among other things, in combination with the resistors of the voltage divider 343, 344, can contribute to a gain roll-off at higher frequencies. In certain examples, a capacitor 360, 361 can be coupled between the control node of the buffer driver transistor (Q13, Q14) and a conduction node of the buffer transistor (Q11, Q12) to provide a little more bandwidth instead of using relatively small resistances for the voltage divider 343, 344.

The emitter followers comprised of the buffer diver transistor (Q13, Q14) and corresponding current source (345, 346) can allows the control node of the buffer transistor (Q11, Q12) to be driven with a signal in the same phase as the output (+V_{OUT}, −V_{OUT}) and with a fraction of the full swing of the output voltage (V_{OUT}). The buffer transistors (Q11, Q12), although in a cascode configuration to pass the current regulated by the input transistors (Q9, Q10), also can act as emitter followers and thus, the voltage swing across the collector and emitter of the buffer transistors (Q11, Q12) is limited by the voltage swing derived from the output voltage (V_{OUT}) via the corresponding voltage divider (343, 344). The limited voltage swing of the buffer transistors (Q11, Q12) can then limit the voltage swing across the input transistors (Q9, Q10)

In certain examples, the above solution can provide a simplified, yet elegant, circuit that can provide a full output swing of the output voltage (V_{OUT}) that is about double the breakdown voltage (B_{Vce}) of each of the stacked amplifier transistors (Q9, Q10, Q11, Q12) and the buffer driver transistors (Q13, Q14). Also, it is possible to extend this solution to provide an output voltage that is K times the breakdown voltage, where K is an integer number greater than one and is indicative of the number of stacked buffer and input transistors. As a result, the amplifier can employ comparatively smaller and more dynamic transistor than a conventional configuration which can allow for an efficient and robust high-frequency amplifier.

In certain examples, the differential amplifier can include a current source to couple the input transistors to a supply rail and to allow for a good range of common mode voltage to be received on the input signals (+V_{IN}, −V_{IN}). However, to conserve voltage headroom and reduce power, both of which would be consumed by a current source, the input transistors (Q9, Q10) can be coupled to a supply rail (e.g., V_{CC}) via an inductor 347. At high frequency, the inductor 347 appears as a high impedance, just as a current source would, and the circuit behaves accordingly. Each branch can include a resistor-inductor network 348, 349 located between the input transistor (Q9, Q10) and the buffer transistor (Q11, A12) to assist with rise and fall times at high frequency. Such improvement can extend the bandwidth of the circuit. More particularly, the inductor assists with faster rise and fall times while the resistor helps dampen ringing associated with the inductors.

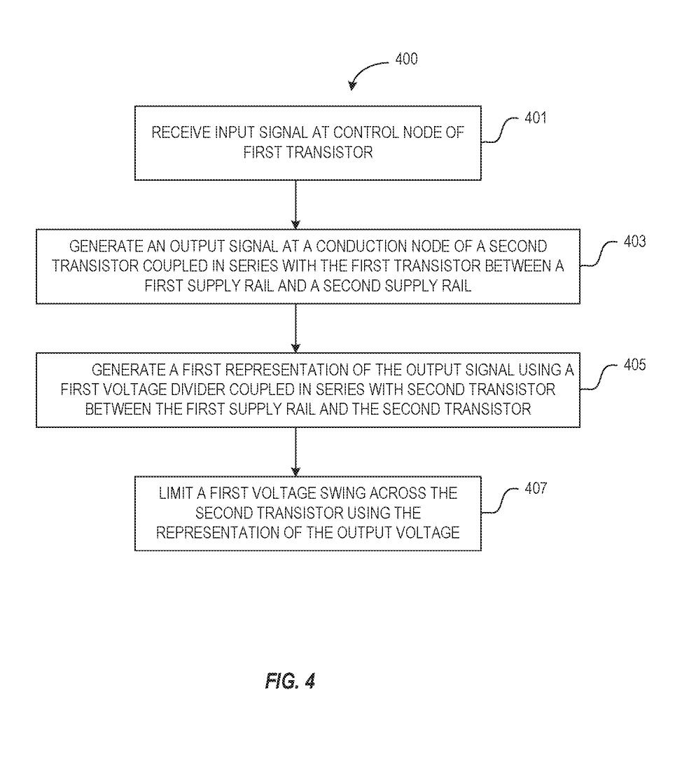

FIG. 4 illustrates generally a flowchart of an example method of operating a modulator driver or modulator driver amplifier. At 401, the modulator can receive an input signal at a control node of a first transistor. In some examples, the first transistor can be one or a pair of input transistors for receiving a differential input signal. In certain examples the input signal can be a small-signal modulation signal, such as modulation signal having a maximum voltage swing of 500 millivolts or less. At 403, the modulator driver can generate an output signal at a conduction node of a second transistor coupled in series with the first transistor between a first supply rail and a second supply rail. In certain examples, the output signal can be a driver signal for a modulator such as an optical or laser modulator and can have a maximum voltage swing of 3 volts or more. In certain examples, the modulator driver can be a high-speed device rate for 40 GHz or more and can use transistors having a collector-emitter breakdown voltage rating of less than the output signal voltage swing. In certain examples, the collector-emitter breakdown voltage rating of the first and second transistors can be less than 2 volts or about 1.8 volts. At 405, the modulator driver can generate a first representation of the output signal using a first voltage divider coupled in series with second transistor between the first supply rail and the second transistor. At 407, the modulator driver can limit a first voltage swing across the second transistor using the representation of the output voltage. Such a limiting can spread the voltage swing of the output signal across the stack of transistors including the first and second transistors, such that a voltage swing across any one of the stack transistors does not exceed the collector-emitter breakdown voltage rating of the transistor and the modulator driver can take advantage of the high-speed characteristics of transistors that typically have lower collector-emitter breakdown voltage ratings.

### EXAMPLES AND ADDITIONAL NOTES

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A modulator driver comprising:
a first transistor configured to receive a first input signal having a first voltage swing;
a second transistor coupled in series with the first transistor, the second transistor configured to provide a representation of the first input signal as a first output signal of the modulator driver, the first output signal having a second voltage swing greater than the first voltage swing; and
a third transistor configured to limit a third voltage swing across the second transistor.

2. The modulator driver of claim 1, wherein the modulator driver is rated for a data rate of 40 GHz or higher.

3. The modulator driver of claim 1, including an inductor-resistor network coupled in series with the first and second transistors.

4. The modulator driver of claim 1, including a voltage divider coupled in series with the first and second transistors.

5. The modulator driver of claim 4, wherein the voltage divider couples an output node of the second transistor with a first supply rail of the modulator driver, the output node configured to provide the output signal.

6. The modulator driver of claim 4, wherein the voltage divider is coupled to a control node of the third transistor.

7. The modulator driver of claim 1, wherein the first transistor, the second transistor, and the third transistor are bipolar junction transistors (BJTs).

8. The modulator driver of claim 7, wherein an emitter of the third transistor is bias with a first current source; and
wherein the emitter of the third transistor is coupled to a control node of the second transistor.

9. The modulator driver of claim 8, wherein an emitter of the first transistor is coupled to a second supply rail via a first inductor.

10. The modulator driver of claim 1, including:
a fourth transistor configured to receive a second input signal;
a fifth transistor coupled in series with the fourth transistor, the fifth transistor configured to provide a representation of the second input signal as a second output signal of the modulator driver;
a sixth transistor configured to limit a fourth voltage swing across the fifth transistor;
wherein the first and second input signal are a differential input signal having the first voltage swing; and
wherein the first and second output signals are a differential output signal of the modulator driver having the second voltage swing.

11. The modulator driver of claim 10, wherein the second voltage swing is greater than a breakdown voltage of any one of the first, second, third, fourth, fifth and sixth transistor.

12. A method of operating a driver amplifier, the method comprising:
receiving an input signal at a control node of a first transistor;
generating an output signal at a conduction node of a second transistor coupled in series with the first transistor between a first supply rail and a second supply rail;
generating a first representation of the output signal using a first voltage divider coupled in series with second transistor between the first supply rail and the second transistor; and
limiting a first voltage swing across the second transistor using the representation of the output signal.

13. The method of claim 12, wherein limiting the voltage across the second transistor includes receiving the representation of the output signal a control node of a third transistor coupled between the first supply rail and a control node of the second transistor.

14. The method of claim 13, wherein the first transistor is a bipolar junction transistor (BJT).

15. The method of claim 14, wherein the second transistor is a BJT.

16. The method of claim 15, wherein the third transistor is a BJT.

17. The method of claim 12, wherein the receiving an input signal at a control node of a first transistor includes receiving a differential input signal at a control node of a first transistor and a control node of a fourth transistor;
wherein the generating an output signal includes generating differential output signal at the conduction node of the second transistor and a conduction node of a fifth transistor:
wherein the fifth transistor is coupled in series with the fourth transistor between the first supply rail and the second supply rail; and
wherein the method further comprises:
generating a second representation of the output signal using a second voltage divider coupled in series with fifth transistor between the first supply rail and the conduction node of the fifth transistor; and
limiting a second voltage swing across the fifth transistor using the second representation of the output signal.

18. A system comprising:
a carrier signal generator configured to generate a carrier signal;
a modulator configured to modulate the carrier signal based on a driver signal;
a modulator driver configured to receive an input modulation signal, and to provide the driver signal based on an amplified representation of the input modulation signal, wherein the modulation driver includes an output stage comprising:
a pair of input transistors configured to receive a differential representation of the modulation signal, the differential representation having a first voltage swing;
a pair of buffer transistors coupled in series with a corresponding one of the pair of input transistors, each of the buffer transistor of the pair of buffer transistors configured to provide a representation of a corresponding input signal of the differential representation as a portion of the driver signal, the driver signal having a differential voltage swing greater than the first voltage swing; and
a pair of buffer driver transistors configured to limit a third voltage swing across a corresponding one of the buffer transistors of the pair of buffer transistors.

19. The system of claim 18, wherein the carrier signal generator is a laser and the carrier signal is a laser signal.

20. The system of claim 19, wherein each of the pair of input transistors, each of the pair of buffer transistors, and each of the pair of buffer driver transistors is a bipolar junction transistor having a collector-emitter breakdown voltage rating less than 2 volts.

21. The system of claim 20, wherein the input modulation signal is configured to have a maximum voltage swing of 500 millivolts or less; and
wherein the driver signal is configured to have a maximum voltage swing of 3 volts or more.
